(19) United States
(12) Patent Application Publication
(10) Pub. No.: US 2009/0212373 A1
(43) Pub. Date: Aug. 27, 2009

(54) SEMICONDUCTOR DEVICE

(75) Inventors: Taichi KARINO, Matsumoto City (JP); Akio KITAMURA, Matsumoto City (JP)

Correspondence Address: ROSSI, KIMMS & McDOWELL LLP., 20609 Gordon Park Square, Suite 150, Ashburn, VA, 20147, US

(73) Assignee: FUJI ELECTRIC DEVICE TECHNOLOGY CO., LTD., Tokyo (JP)

(21) Appl. No.: 12/393,906

(22) Filed: Feb. 26, 2009

(30) Foreign Application Priority Data
Feb. 27, 2008 (JP) 2008-046759

(51) Int. Cl. H01L 27/092; H01L 27/08; H01L 27/088

(52) U.S. Cl. 257/369; 257/501; 257/392; 257/E27.061; 257/E27.062; 257/E27.046

(57) ABSTRACT

A semiconductor device facilitates securing a high breakdown voltage and reducing a chip area thereof includes a low-potential gate driver circuit disposed on a semiconductor substrate, a high-breakdown-voltage junction edge-termination structure disposed in a peripheral portion of a high-potential gate driver circuit, disposed on the semiconductor substrate, for separating the low-potential gate driver circuit and the high-potential gate driver circuit from each other. A trench is disposed in the edge termination structure and between an n⁺-type source layer and an n⁺-type drain layer in a level shift circuit in the high-potential gate driver circuit, and an oxide film fills the trench to form a dielectric region in trench.

### BACKGROUND

The present invention relates to a power IC and such a semiconductor device that include a MOSFET exhibiting a high breakdown voltage.

In an integrated circuit employed for a driver exhibiting a high breakdown voltage used for controlling the drive of a power supply apparatus and such apparatuses, a high-potential section and a low-potential section are disposed on a same substrate for reducing the manufacturing costs thereof and the chip area thereof. For separating the high-potential section and the low-potential section from each other, a junction separation structure that uses a pn-junction and a dielectric separation structure that uses a dielectric material such as silicon oxide (SiO₂) are generally employed.

For example, in forming the junction separation structure using a p-type substrate, a lightly doped n-type epitaxial layer is formed on the p-type substrate. Then, a p-type layer is formed by diffusion into the deep portion of the epitaxial layer. Through the steps described above, an n-type layer island is formed three-dimensionally in the p-type layer by the pn-junction. A driver circuit configured by a CMOS device and such a device is disposed in the n-type layer island. By applying a reverse bias voltage to the n-type layer island and the p-type substrate, a depletion layer is formed in the junction portion. The n-type layer island is separated electrically by the static capacitance caused in the depletion layer and a high breakdown voltage is obtained.

For forming the dielectric separation structure, SiO₂ is formed, for example, selectively on a silicon substrate and circuits are disposed in the silicon regions separated electrically by SiO₂. In the dielectric separation structure, the silicon regions are made to work with reference to the respective reference potentials different from each other to realize a high breakdown voltage.

Due to the use of an epitaxial wafer for a substrate, however, the manufacturing costs of the junction separation structure are high. Another junction separation structure that uses a usual silicon wafer and a planer junction has been known to the persons skilled in the art. See, for example, Japanese Unexamined Patent Application Publication No. Hei. 9 (1997)-55498 and counterpart U.S. Pat. No. 6,124,628). A combined separation structure, which separates the high-potential section from the low-potential section with a junction separation structure and the device in the high-potential section from the device in the low-potential section with a trench, has been known to the persons skilled in the art. See, for example, Japanese Unexamined Patent Application Publication No. 2000-58673.

FIG. 4 is a block diagram of a controller used for inverters for illumination devices. The controller includes an IC 30 exhibiting a high breakdown voltage, IGBTs Q1 and Q2, and diodes D1 and D2. The diodes D1 and D2 are connected in parallel to the IGBTs Q1 and Q2, respectively, configuring a half-bridge circuit. The half-bridge circuit is configured for making the back electromotive force caused in the load inductance flow through IGBTs Q1 and Q2,

In FIG. 4, the IC 30 exhibits a high breakdown voltage integrates control circuit 31, low-potential gate driver circuit (low-potential-side low-breakdown-voltage circuit: hereinafter referred to as “GDUL”) 32, and high-breakdown-voltage section 35 exhibiting a high-breakdown-voltage for one-phase of a half-bridge circuit on a semiconductor substrate. On the practical IC substrate, half-bridge circuits for three-phases are integrated.

Control circuit 31 determines the ON- and OFF-timings of the IGBTs Q1 and Q2 in response to a signal fed from a not-shown input/output (I/O) terminal. GDUL 32 drives IGBT Q2 connected to the low potential side of a power supply. High-breakdown-voltage section 35 includes high-potential gate driver circuit (high-potential-side low-breakdown-voltage circuit: hereinafter referred to as “GDUH”) 33 and level shift circuit 34. The GDUH 33 drives the IGBT Q1 connected to the high potential side of the power supply. The level shift circuit 34 shifts the level of the control signal fed from the control circuit 31 to the GDUH 33.

Assuming that a main power supply voltage V_{CC} is 600 V, when a voltage of 615 V, consisting of the main power supply voltage V_{CC} of 600 V and a gate voltage V_{DD} of 15 V added thereto, is applied to the gate electrode of the IGBT Q1 connected to the high potential side of the power supply, the IGBT Q1 is brought into the ON-state thereof. By bringing the IGBT Q2 connected to the low potential side of the power supply into the ON-state thereof after bringing IGBT Q1 into the OFF-state thereof, an AC rectangular waveform having a frequency corresponding, for example, to the gate switching frequency is generated at output terminal V_{OUT}.

When the IGBT Q1 is in the ON-state thereof, the potential at output terminal V_{OUT} is almost equal to the potential of the main power supply voltage V_{CC}. When the IGBT Q2 is in the ON-state thereof, the potential at output terminal V_{OUT} is almost equal to the ground potential GND. Therefore, it is necessary to obtain a dielectric breakdown voltage, equal to or higher than the sum of the main power supply voltage V_{CC} and the gate voltage V_{DD}, between the GDUH 33 included in high-breakdown-voltage section 35 and the control circuit 31 including a signal processing circuit and a driver circuit, the breakdown voltages thereof are low.

Level shift circuit 34 shifts the potential levels of the control signals fed from the control circuit 31 including the signal processing circuit and the driver circuit. The control signals, the potential levels thereof are shifted, are fed to the GDUH 33. The GDUH 33 feeds a control signal to the IGBT Q1 to make the IGBT Q1 conduct ON- and OFF-operations in response to a control signal. It is necessary for the semiconductor substrate, on which the high-breakdown-voltage section 35 is mounted, to have a high-breakdown-voltage separation structure that facilitates obtaining a sufficient dielectric strength including the above-described dielectric separation structure, the above-described junction separation structure, a high-breakdown-voltage junction edge-termination structure, etc.

Now the structure of the high-breakdown-voltage section 35 will be described below with reference to FIG. 5. FIG. 5 is a top plan view showing the structure of the conventional high-breakdown-voltage section illustrated in FIG. 4. Metal wiring 108 (shown in FIG. 6) is not shown in FIG. 5 in order to clearly illustrate the structure of high-breakdown-voltage section 35.

In the following descriptions, the n-type semiconductor or the p-type semiconductor is a semiconductor, in which electrons or holes are majority carriers. The suffix “+” on the shoulder of the letter “n” or “p” indicating the conductivity type of a semiconductor indicates that the semiconductor is doped relatively heavily. The suffix “−” on the shoulder of the letter “n” or “p” indicating the conductivity type of a semiconductor indicates that the semiconductor is doped relatively lightly.

As shown in FIG. 5, the GDUH 33, which should be separated from other circuits with a high breakdown voltage, is formed in an island electrically separated from other circuits by a junction separation structure or a dielectric separation structure and the peripheral portion thereof is surrounded by high-breakdown-voltage junction edge-termination structure 36. The high-breakdown-voltage junction edge-termination structure 36 is the edge termination structure of a junction, to which a high voltage is applied for insulation. (Hereinafter the high-breakdown-voltage junction edge-termination structure 36 will be referred to simply as “edge termination structure 36”.)

In edge termination structure 36, a MOSFET that exhibits a high breakdown voltage and works for level shift circuit 34 is disposed. The MOSFET includes p-type base layer 103, n⁺-type drain layer 104, n⁺-type source layer 105, and gate electrode 107. The GDUH 33 is a high-potential-side low-breakdown-voltage circuit. The circuits around the edge termination structure 36 belong to the low-potential-side low-breakdown-voltage circuit.

V_{DH} pad 38, V_{DL} pad 39, and V_{Q} pad 40 are disposed in the GDUH 33. V_{DH} pad 38, V_{DL} pad 39, and V_{Q} pad 40 are connected to the other parts of the control circuit by bonding wires 37. V_{DH} pad 38 is connected to the high potential side of the gate electrode. V_{DL} pad 39 is connected to the low potential side of the gate electrode. V_{Q} pad 40 is connected to the IGBT Q1 to output a control signal for driving the IGBT Q1 from the GDUH 33.

FIG. 6 is a cross sectional view showing the cross sectional structure along C-C′ in FIG. 5. As shown in FIG. 6, the GDUH 33 is separated electrically from the level shift circuit 34 by a field oxide film 111. A MOSFET 210 exhibiting a high breakdown voltage is disposed in the level shift circuit 34. In MOSFET 210, an n⁻-type extended well layer 102 and a p-type base layer 103 are disposed in the surface portion of a p-type substrate 101, such that the n⁻-type extended well layer 102 and the p-type base layer 103 are spaced apart from each other. In the surface portion of the n⁻-type extended well layer 102, a n⁺-type drain layer 104 is disposed. For obtaining a high breakdown voltage, the n⁺-type drain layer 104 is disposed such that the n⁺-type drain layer 104 is spaced apart from the junction plane of p-type substrate 101. An n⁺-type source layer 105 is disposed in the surface portion of p-type base layer 103.

A field oxide film 110 is disposed in the surface portion of the n⁻-type extended well layer 102 between the n⁺-type drain layer 104 and the extended portion of the p-type substrate 101 extended between the n⁻-type extended well layer 102 and the p-type base layer 103. A gate electrode 107 is disposed above the n⁺-type source layer 105 and the n⁻-type extended well layer 102 with a gate oxide film 106 interposed therebetween. The gate electrode 107 is made, for example, of polysilicon. A field oxide film 111 is disposed in the other part of the surface portion of the n⁻-type extended well layer 102 such that the field oxide film 111 is in contact with the n⁺-type drain layer 104.

The devices included in the GDUH 33 are disposed in a n-type well layer 122 connected to the n⁻-type extended well layer 102. The devices disposed in the GDUH 33 include, for example, a p-MOSFET 200 and an n-MOSFET 201. In p-MOSFET 200, a first p⁺-type layer 112 and a second p⁺-type layer 113 are disposed in the surface portion of the n-type well layer 122 such that the first p⁺-type layer 112 and the second p⁺-type layer 113 are spaced apart from each other. A gate electrode 115 is disposed above the extended portion of the n-type well layer 122, extended between first p⁺-type layer 112 and the second p⁺-type layer 113, with the gate oxide 114 film interposed between gate electrode 115 and the extended portion of n-type well layer 122.

A field oxide film 116 is disposed in the surface portion of n-type well layer 122. The n-MOSFET 201 is spaced apart from the p-MOSFET 200 by the field oxide film 116. In the n-MOSFET 201, a p-type well region 117 is disposed in the surface portion of the n-type well layer 122 on the opposite side of the second p⁺-type layer 113. In the surface portion of the p-type well region 117, a first n⁺-type layer 118 and a second n⁺-type layer 119 are disposed such that the first n⁺-type layer 118 and the second n⁺-type layer 119 are spaced apart from each other. A gate electrode 121 is disposed above the extended portion of the p-type well region 117, extended between the first n⁺-type layer 118 and the second n⁺-type layer 119, with a gate oxide film 120 interposed between the gate electrode 121 and the extended portion of p-type well region 117.

Metal wiring 108 is connected electrically to n⁺-type drain layer 104 in level shift circuit 34, gate electrode 115 of p-MOSFET 200, and gate electrode 121 of n-MOSFET 201. The control signal, the level of which is shifted from low one to high one by level shift circuit 34, is fed to GDUH 33 via metal wiring 108. Metal wiring 108 is connected also to V_{DH} pad 38 shown in FIG. 5 via a not-shown resistor.

FIG. 7 is a cross sectional view showing the cross sectional structure along D-D′ in FIG. 5. As shown in FIG. 7, the GDUH 33 is separated electrically from the edge termination structure 36 by the field oxide film 111. Since the structure of the GDUH 33 is similar to the structure shown in FIG. 6, the duplicated descriptions will be omitted for the sake of simplicity. In the edge termination structure 36, the p-type base layer 103 is disposed in the surface portion of the p-type substrate 101, in which the GDUH 33 is formed, such that the p-type base layer 103 is spaced apart from the n⁻-type extended well layer 102.

When the potential of the n⁻-type extended well layer 102 in the GDUH 33 in conventional high-breakdown-voltage section 35 shown in FIGS. 6 and 7 changes between 0 V and 600 V, it is necessary for edge termination structure 36 to exhibit a breakdown voltage of more than 600 V. In this case, it is necessary for field oxide film 111 to be 60 μm or more in thickness.

For isolating the high-potential section with a desired breakdown voltage by the technique disclosed in Japanese Unexamined Patent Application Publication No. Hei. 9 (1997)-55498, the width of the high-breakdown-voltage junction edge-termination structure should be large enough, causing a widened chip area. Although the technique disclosed in Japanese Unexamined Patent Application Publication No. 2000-58673 does not widen the chip area, it is impossible for the technique to separate the high-potential section and the low-potential section in the same semiconductor substrate with a breakdown voltage of the 600 V class or a higher breakdown voltage class.

In view of the foregoing, it would be desirable to obviate the problems described above, namely, it would be also desirable to provide a semiconductor device, which exhibits a high breakdown voltage but the chip area of which is small.

### SUMMARY OF THE INVENTION

The present invention provides a semiconductor device that exhibits a high breakdown voltage while having a small chip area. In one embodiment, a semiconductor device is provided that controls one or more power devices, wherein the one or more power devices include a first main terminal connected to a high potential side of a high-voltage power supply and a second main terminal connected to a load. The semiconductor device includes a semiconductor substrate of a first conductivity type, a low-potential-side low-breakdown-voltage circuit, to which a current is fed from a first low-voltage power supply, the reference of which is set on the low potential side of a high-voltage power supply, the low-potential-side low-breakdown-voltage circuit being on the semiconductor substrate, a high-potential-side low-breakdown-voltage circuit, to which a current is fed from a second low-voltage power supply, the reference of which is set on the first or second main terminal of the one or more power devices, the high-potential-side low-breakdown-voltage circuit being on the semiconductor substrate, the high-potential-side low-breakdown-voltage circuit being spaced apart from the low-potential-side low-breakdown-voltage circuit, a high-breakdown-voltage junction edge-termination structure, to which a high voltage is applied for separating the high-potential-side low-breakdown-voltage circuit and the low-potential-side low-breakdown-voltage circuit electrically from each other, the high-breakdown-voltage junction edge-termination structure being on the semiconductor substrate, the high-breakdown-voltage junction edge-termination structure surrounding the high-potential-side low-breakdown-voltage circuit, a trench in the high-breakdown-voltage junction edge-termination structure, the trench surrounding the high-potential-side low-breakdown-voltage circuit, a first well layer of a second conductivity type in the surface portion of the semiconductor substrate along the inner side of the trench, and a second well layer of the second conductivity type in the surface portion of the semiconductor substrate along the outer side of the trench, the second well layer being in contact with the first well layer.

The semiconductor device preferably includes a first MIS transistor in the first well layer in the high-potential-side low-breakdown-voltage circuit, and a second MIS transistor exhibiting a high breakdown voltage, the second MIS transistor including a drain layer in the high-breakdown-voltage junction edge-termination structure, a gate electrode outside the high-breakdown-voltage junction edge-termination structure, and a source layer outside the high-breakdown-voltage junction edge-termination structure.

The second MIS transistor preferably includes a drain layer of the second conductivity type in the surface portion of the first well layer, a base layer of the first conductivity type around the second well layer in the surface portion of the semiconductor substrate, a source layer of the second conductivity type in the surface portion of the base layer, the source layer being spaced apart from the second well layer, and a gate electrode above the source layer, the base layer and the second well layer between the source layer and the trench with an insulator film interposed therebetween.

The high-potential-side low-breakdown-voltage circuit preferably includes a level shift circuit that shifts the level of a control signal fed to the high-potential-side low-breakdown-voltage circuit, wherein the level shift circuit preferably includes a base layer of the first conductivity type in the surface portion of the semiconductor substrate, a source layer of the second conductivity type in the surface portion of the base layer; the second well layer of the second conductivity type in the surface portion of the semiconductor substrate, the second well layer being spaced apart from the source layer; a drain layer of the second conductivity type in the surface portion of the second well layer, a trench in the surface portion of the second well layer between the source layer and the drain layer, an insulator film filling the trench, a gate electrode above the source layer, the second well layer and a source side portion of the trench with a gate oxide film interposed therebetween, and a metal wiring connected to the drain layer.

The high-breakdown-voltage junction edge-termination structure preferably includes a base layer of the first conductivity type in the surface portion of the semiconductor substrate, the second well layer of the second conductivity type in the surface portion of the semiconductor substrate, the second well layer being in contact with the base layer, a trench in a surface portion of the second well layer, the trench being spaced apart from a source layer, and an insulator film filling the trench.

The high-potential-side low-breakdown-voltage circuit preferably includes the first well layer of the second conductivity type in the surface portion of the semiconductor substrate, the first well layer being in contact with the second well layer; a first MOSFET of the first conductivity type in the surface portion of the first well layer; a third well layer of the first conductivity type in the surface portion of the first well layer, the third well layer being spaced apart from the first MOSFET, a second MOSFET of the second conductivity type in the surface portion of the third well layer. The first MOSFET preferably includes a first layer of the first conductivity type in the surface potion of the first well layer, a second layer of the first conductivity type in the surface potion of the first well layer, the second layer being spaced apart from the first layer, a first gate electrode above the first layer and the second layer with a first gate oxide film interposed between the first gate electrode and the first and second layers. The second MOSFET preferably includes a third layer of the second conductivity type in the surface portion of the third well layer, a fourth layer of the second conductivity type in the surface portion of the third well layer, the fourth layer being spaced apart from the third layer, a second gate electrode above the third layer and the fourth layer with a second gate oxide film interposed between the second gate electrode and the third and fourth layers, and a metal wiring connected electrically to the first gate electrode of the first MOSFET and the second gate electrode of the second MOSFET.

According to the invention, a trench is disposed in the high-breakdown-voltage junction edge-termination structure and a dielectric material is buried in the trench. Since it is possible to make the dielectric region in the trench carry the electric charges, it is possible to narrow the oxide film width that separates the high-potential section and the low-potential section from each other. Accordingly, since it is possible to reduce the area of the high-breakdown-voltage junction edge-termination structure, it is possible to reduce the chip area. Thus, the semiconductor device according to the invention facilitates reducing the chip area while securing a high breakdown voltage.

Other features and advantages of the invention will become apparent to those skilled in the art from the following detailed description of the preferred embodiments of the invention.

### BRIEF DESCRIPTIONS OF THE DRAWINGS

The invention will be described with reference to certain preferred embodiments and the accompanying drawings, wherein:

FIG. 1 is a top plan view of a semiconductor device according to the invention;

FIG. 2 is a cross sectional view showing the cross sectional structure along A-A′ in FIG. 1;

FIG. 3 is a cross sectional view showing the cross sectional structure along B-B′ in FIG. 1;

FIG. 4 is a block diagram of a controller used for inverters for illuminations;

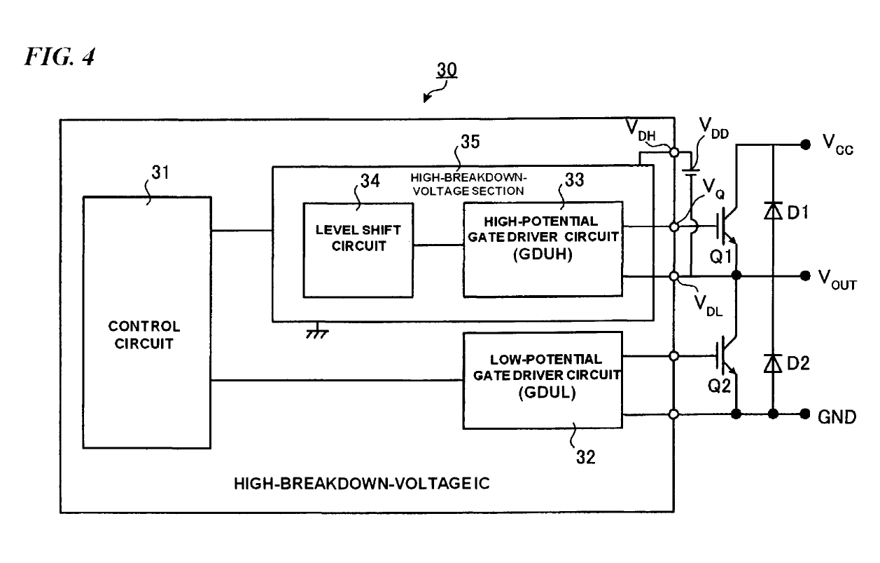

FIG. 5 is a top plan view showing the structure of the high-breakdown-voltage section in FIG. 4;

FIG. 6 is a cross sectional view showing the cross sectional structure along C-C′ in FIG. 5; and

FIG. 7 is a cross sectional view showing the cross sectional structure along D-D′ in FIG. 5;

### DETAILED DESCRIPTION OF THE PREFERRED EMBODIMENTS

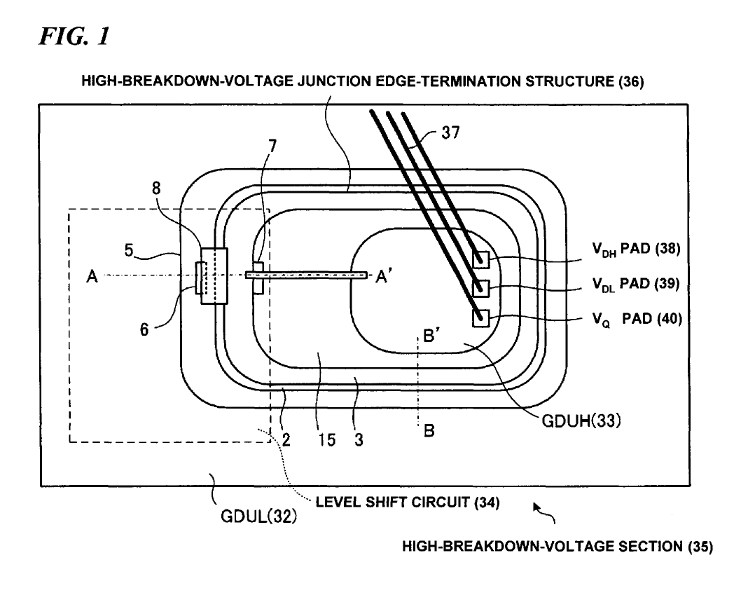

FIG. 1 is a top plan view of a semiconductor device according to the invention. The semiconductor device shown in FIG. 1 is employed for a high-potential gate driver circuit (hereinafter referred to as “GDUH”) 33 of a controller used for inverters that provide illumination. The semiconductor device according to the invention shown in FIG. 1 is formed in an island separated electrically from low-potential gate driver circuit (hereinafter referred to as “GDUL”) 32 by a junction separation structure or a dielectric separation structure, and the peripheral portion thereof is surrounded by a high-breakdown-voltage junction edge-termination structure (hereinafter referred to simply as “edge termination structure”) 36. In the semiconductor device, a lateral MIS transistor, which exhibits a high-breakdown voltage and works for level shift circuit 34, is disposed. The lateral MIS transistor includes p-type base layer 5, n⁺-type source layer 6, n⁺-type drain layer 7, and gate electrode 8.

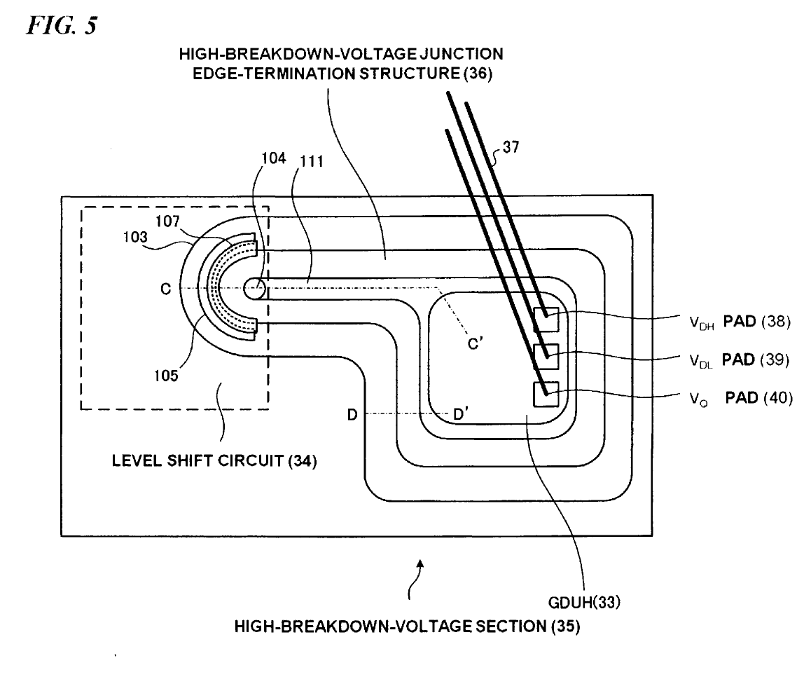

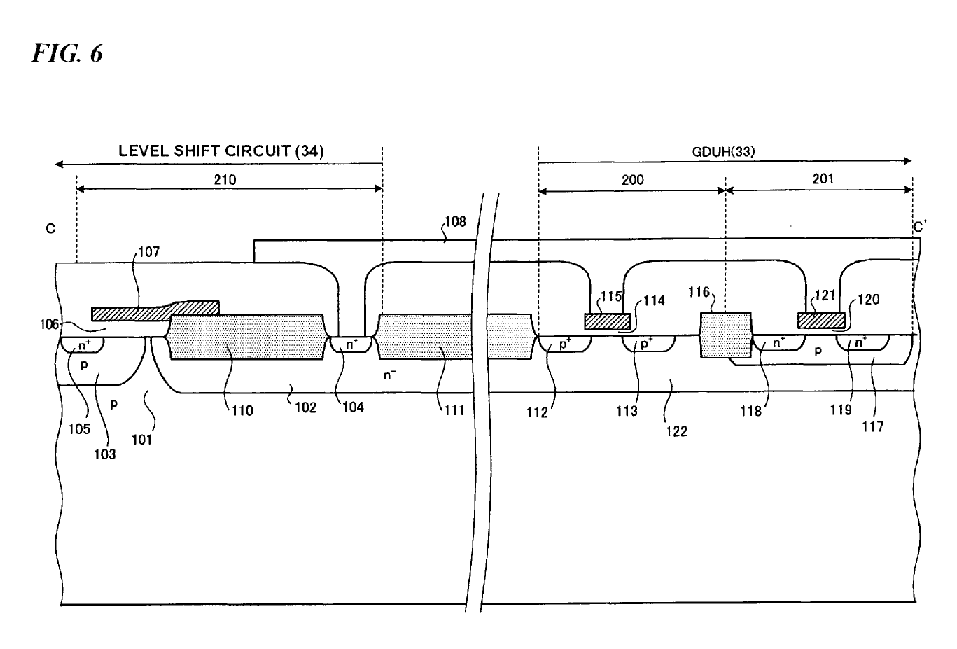

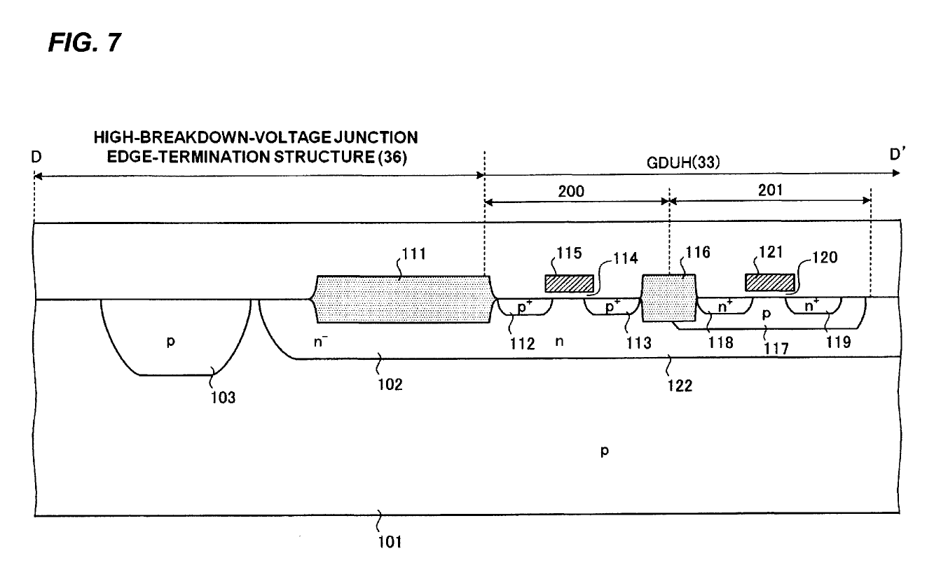

V_{DH} pad 38, V_{DL} pad 39, and V_{Q} pad 40 are disposed in GDUH 33 and are connected to the other parts of the controller by bonding wires 37. V_{DH} pad 38 is connected, for example, to the high potential side of the gate electrode. V_{DL} pad 39 is connected, for example, to the low potential side of the gate electrode. V_{Q} pad 40 is connected, for example, to an IGBT connected to the high potential side of a power supply to output a control signal for driving the IGBT from GDUH 33. The semiconductor device according to the invention is different from the conventional structures shown in FIGS. 5 through 7, in that a trench 3 is disposed in the edge termination structure 36 and the level shift circuit 34.

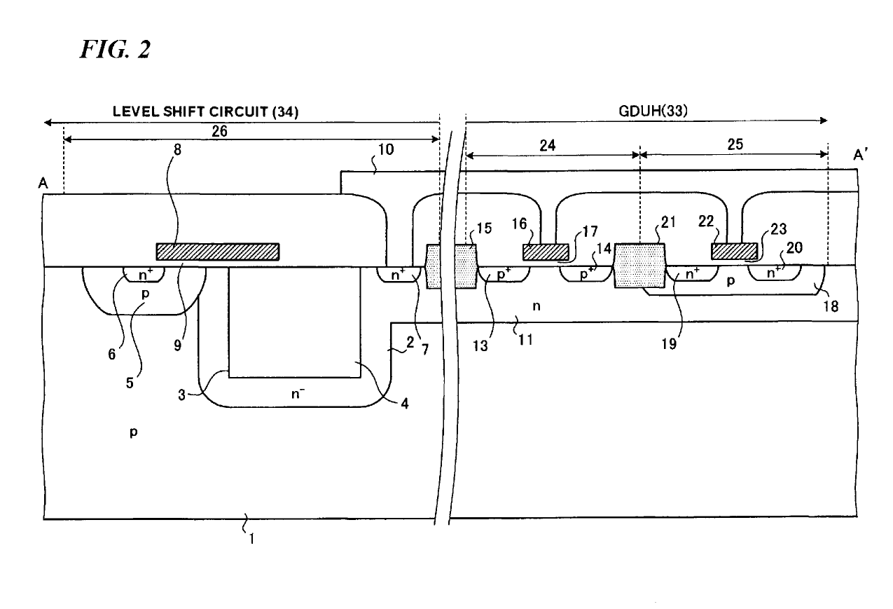

FIG. 2 is a cross sectional view showing the cross sectional structure along A-A′ in FIG. 1. As shown in FIG. 2, the semiconductor device according to the invention is manufactured using p-type semiconductor substrate 1. GDUH 33 is separated electrically from the level shift circuit 34 by a field oxide film 15. In the surface portion of p-type substrate 1, n⁻-type extended well layer (second well layer) 2 is disposed.

In the level shift circuit 34, p-type base layer 5 is disposed in the surface portion of p-type semiconductor substrate 1, such that p-type base layer 5 is in contact with n⁻-type extended well layer 2. An n⁺-type source layer 6 is disposed in the surface portion of p-type base layer 5. The specific resistance of n⁺-type source layer 6 is lower than the specific resistance of n⁻-type extended well layer 2. An n⁺-type drain layer 7 is disposed in the surface portion of n⁻-type extended well layer 2. The specific resistance of n⁺-type drain layer 7 is lower than the specific resistance of the n⁻-type extended well layer 2.

The trench 3 is disposed in the surface portion of the n⁻-type extended well layer 2 between the p-type base layer 5 and the n⁺-type drain layer 7. The drain-side wall of the trench 3 may be in contact with the n⁺-type drain layer 7 with no problem. For example, the trench 3 is 20 μm in width and 20 μm in depth. The trench 3 is filled with a dielectric material such as an oxide film, resulting in a dielectric region 4. The dielectric region 4 may includes dielectric layers formed along the inner walls of the trench 3 and a dielectric cover plate closing the opening of the trench 3 such that a cavity is formed in the trench 3. By making the dielectric region 4 carry electric charges, a MOSFET exhibiting a high breakdown voltage is formed in a narrow area.

The gate electrode 8 is disposed above the n⁺-type source layer 6, the extended portion of the p-type base layer 5 extends between the n⁺-type source layer 6 and the n⁻-type extended well layer 2, the n⁻-type extended well layer 2 is in contact with the source side of trench 3, and the trench 3 with the gate oxide film 9 interposed therebetween. Thus, a MOSFET 26 exhibits a high breakdown voltage, that is a MIS transistor exhibiting a high breakdown voltage, is formed.

A first n-type well layer 11 is connected to the n⁻-type extended well layer 2 below the field oxide film 15. The first n-type well layer 11 and the n⁻-type extended well layer 2 are biased at the same potential. In GDUH 33, a first p⁺-type layer 13 is disposed in the surface portion of the first n-type well layer 11. A second p⁺-type layer 14 is disposed in the other surface portion of the first n-type well layer 11 such that the second p⁺-type layer 14 is spaced apart from the first p⁺-type layer 13. The first p⁺-type layer 13 and the n⁺-type drain layer 7 are spaced apart from each other by the field oxide film 15. A gate electrode 16 is disposed above the first p⁺-type layer 13, the extended portion of the first n-type well layer 11 extended between first p⁺-type layer 13 and the second p⁺-type layer 14, and the second p⁺-type layer 14 with the gate oxide film 17 interposed therebetween. Thus, a p-MOSFET 24 is formed, which is a MIS transistor, the base of which is the first n-type well layer 11.

A third p-type well layer 18 is disposed in the surface portion of the first n-type well layer 11 such that the third p-type well layer 18 is spaced apart from second p⁺-type layer 14 by the field oxide film 21. The first n⁺-type layer 19 is disposed in the surface portion of third p-type well layer 18. The second n⁺-type layer 20 is disposed in the surface portion of the third p-type well layer 18 such that the second n⁺-type layer 20 is spaced part from the first n⁺-type layer 19. A gate electrode 22 is disposed above the first n⁺-type layer 19, the extended portion of the third p-type well layer 18 extends between the first n⁺-type layer 19 and the second n⁺-type layer 20, and the second n⁺-type layer 20 with gate oxide film 23 interposed therebetween. Thus, an n-MOSFET 25 is formed, which is a MIS transistor, the base of which is third n-type well layer 18.

Metal wiring 10 is connected electrically to the n⁺-type drain layer 7 in the level shift circuit 34, the gate electrode 16 of p-MOSFET 24, and the gate electrode 22 of n-MOSFET 25. Control signals, the potential levels thereof are shifted by level shift circuit 34, are fed to GDUH 33.

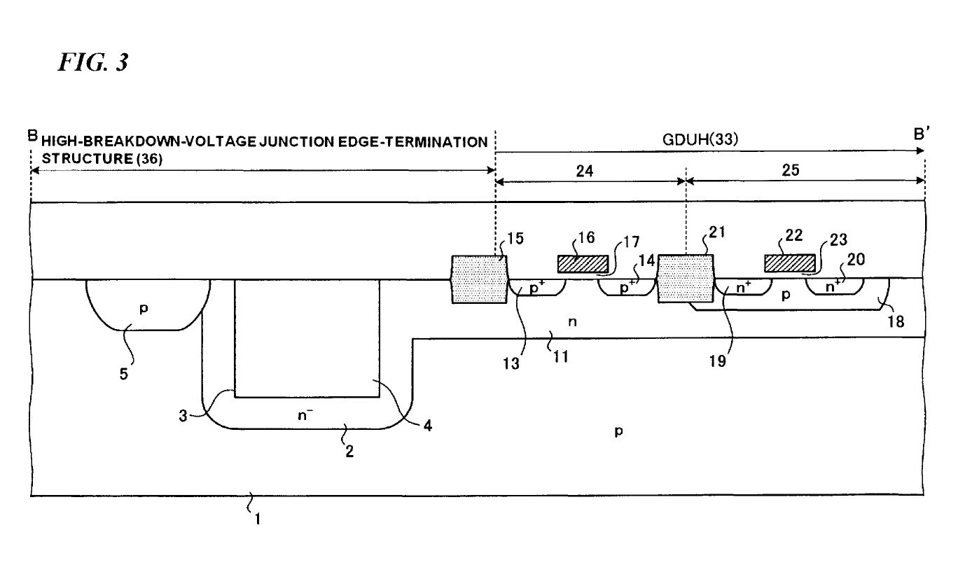

FIG. 3 is a cross sectional view showing the cross sectional structure along B-B′ in FIG. 1. As shown in FIG. 3, GDUH 33 is separated electrically from edge termination structure 36 by field oxide film 15. Since the structure of GDUH 33 is similar to the structure shown in FIG. 2, the duplicated descriptions will be omitted for the sake of simplicity. In the edge termination structure 36, the p-type base layer 5 is disposed in the surface portion of the p-type semiconductor substrate 1 such that p-type base layer 5 is in contact with n⁻-type extended well layer 2. The trench 3 is disposed in the surface portion of the n⁻-type extended well layer 2 such that the trench 3 is spaced apart from the p-type base layer 5. For example, the trench 3 is 20 μm in width and 20 μm in depth. The trench 3 is preferably filled with a dielectric material, such as an oxide film, in the same manner as the trench shown in FIG. 2, resulting in the dielectric region 4.

The semiconductor device according to the invention, which makes the dielectric region 4 in the trench 3 carry the potential, facilitates reducing the areas of the level shift circuit 34 and the edge termination structure 36. In order to obtain a breakdown voltage of 600 V using conventional structures that do not include any trench, it is necessary for the field oxide film 15 that separates the GDUH 33 electrically from the level shift circuit 34 and the edge termination structure 36 to be about 60 μm in width. In contrast, since the dielectric region 4 in the trench 3 of the present invention, which is only 20 μm in width and 20 μm in depth, sustains the breakdown voltage, the areas of the level shift circuit 34 and the edge termination structure 36 of the invention are just one-third as wide as the areas of level shift circuit 34 and edge termination structure 36 in the conventional structures.

As described above, the semiconductor device according to the invention facilitates reducing the chip area while securing a high breakdown voltage. The semiconductor device according to the invention is useful for a MOSFET exhibiting a high breakdown voltage. Specifically, the semiconductor device according to the invention is well suited for power ICs that include a MOSFET exhibiting a high breakdown voltage.

The invention has been described with reference to certain preferred embodiments thereof. It will be understood, however, that modifications and variations are possible within the scope of the appended claims.

This application is based on, and claims priority to, Japanese Patent Application No: 2008-046759, filed on Feb. 27, 2008. The disclosure of the priority application, in its entirety, including the drawings, claims, and the specification thereof, is incorporated herein by reference.

What is claimed is:

1. A semiconductor device that controls one or more power devices, the one or more power devices comprising a first main terminal connected to a high potential side of a high-voltage power supply and a second main terminal connected to a load, the semiconductor device comprising:
a semiconductor substrate of a first conductivity type;
a low-potential-side low-breakdown-voltage circuit, thereto a current is fed from a first low-voltage power supply, a reference thereof is set on a low potential side of the high-voltage power supply, the low-potential-side low-breakdown-voltage circuit being on the semiconductor substrate;
a high-potential-side low-breakdown-voltage circuit, thereto a current is fed from a second low-voltage power supply, a reference thereof is set on the first or second main terminal of the one or more power devices, the high-potential-side low-breakdown-voltage circuit being on the semiconductor substrate, the high-potential-side low-breakdown-voltage circuit being spaced apart from the low-potential-side low-breakdown-voltage circuit;
a high-breakdown-voltage junction edge-termination structure, thereto a high voltage is applied for separating the high-potential-side low-breakdown-voltage circuit and the low-potential-side low-breakdown-voltage circuit electrically from each other, the high-breakdown-voltage junction edge-termination structure being on the semiconductor substrate, the high-breakdown-voltage junction edge-termination structure surrounding the high-potential-side low-breakdown-voltage circuit;
a trench in the high-breakdown-voltage junction edge-termination structure, the trench surrounding the high-potential-side low-breakdown-voltage circuit;
a first well layer of a second conductivity type in a surface portion of the semiconductor substrate along an inner side of the trench; and
a second well layer of the second conductivity type in the surface portion of the semiconductor substrate along an outer side of the trench, the second well layer being in contact with the first well layer.

2. The semiconductor device according to claim 1, the semiconductor device comprising:
a first MIS transistor in the first well layer in the high-potential-side low-breakdown-voltage circuit; and
a second MIS transistor exhibiting a high breakdown voltage, the second MIS transistor comprising a drain layer in the high-breakdown-voltage junction edge-termination structure, a gate electrode outside the high-breakdown-voltage junction edge-termination structure, and a source layer outside the high-breakdown-voltage junction edge-termination structure.

3. The semiconductor device according to claim 2, wherein the second MIS transistor comprises:
a drain layer of the second conductivity type in a surface portion of the first well layer;
a base layer of the first conductivity type around the second well layer in the surface portion of the semiconductor substrate;
a source layer of the second conductivity type in a surface portion of the base layer, the source layer being spaced apart from the second well layer; and
a gate electrode above the source layer, the base layer and the second well layer between the source layer and the trench with an insulator film interposed therebetween.

4. The semiconductor device according to claims 1, wherein the high-potential-side low-breakdown-voltage circuit comprises a level shift circuit that shifts a level of a control signal fed to the high-potential-side low-breakdown-voltage circuit, the level shift circuit comprising:
a base layer of the first conductivity type in the surface portion of the semiconductor substrate;
a source layer of the second conductivity type in a surface portion of the base layer;
the second well layer of the second conductivity type in the surface portion of the semiconductor substrate, the second well layer being spaced apart from the source layer;
a drain layer of the second conductivity type in a surface portion of the second well layer;
a trench in the surface portion of the second well layer between the source layer and the drain layer;
an insulator film filling the trench;
a gate electrode above the source layer, the second well layer and a source side portion of the trench with a gate oxide film interposed therebetween and
a metal wiring connected to the drain layer.

5. The semiconductor device according to claim 1, wherein the high-breakdown-voltage junction edge-termination structure comprises:
a base layer of the first conductivity type in the surface portion of the semiconductor substrate, wherein the second well layer of the second conductivity type in the surface portion of the semiconductor substrate, the second well layer being in contact with the base layer;
a trench in a surface portion of the second well layer, the trench being spaced apart from a source layer; and
an insulator film filling the trench.

6. The semiconductor device according to claim 1, wherein the high-potential-side low-breakdown-voltage circuit comprises:
the first well layer of the second conductivity type in the surface portion of the semiconductor substrate, the first well layer being in contact with the second well layer;
a first MOSFET of the first conductivity type in a surface portion of the first well layer;
a third well layer of the first conductivity type in the surface portion of the first well layer, the third well layer being spaced apart from the first MOSFET;
a second MOSFET of the second conductivity type in a surface portion of the third well layer;
wherein the first MOSFET comprises:
a first layer of the first conductivity type in the surface potion of the first well layer; a second layer of the first conductivity type in the surface potion of the first well layer, the second layer being spaced apart from the first layer; a first gate electrode above the first layer and the second layer with a first gate oxide film interposed between the first gate electrode and the first and second layers; and
wherein the second MOSFET comprises:
a third layer of the second conductivity type in the surface portion of the third well layer; a fourth layer of the second conductivity type in the surface portion of the third well layer, the fourth layer being spaced apart from the third layer; a second gate electrode above the third layer and the fourth layer with a second gate oxide film interposed between the second gate electrode and the third and fourth layers; and a metal wiring connected electrically to the first gate electrode of the first MOSFET and the second gate electrode of the second MOSFET.
